(19) United States
(12) Patent Application Publication
(10) Pub. No.: US 2026/0283054 A1
(43) Pub. Date: Sep. 17, 2026

(54) COMPOSITION OF A SEMICONDUCTOR PACKAGE FOR CRYOGENIC ENVIRONMENTS

(71) Applicant: Micron Technology, Inc., Boise, ID (US)

(72) Inventors: Chen Yu Huang, Taichung (TW); Chong Leong Gan, Taichung (TW)

(21) Appl. No.: 19/190,389

(22) Filed: Apr. 25, 2025

Related U.S. Application Data
(60) Provisional application No. 63/648,059, filed on May 15, 2024.

(51) Int. Cl. H10W 90/00; H05K 1/181; H10B 80/00; H10D 80/30; H10W 74/15; H10W 90/24

(52) U.S. Cl. CPC H10W 90/7295; H05K 1/181; H10B 80/00; H10D 80/30; H10W 90/24; H10W 90/724; H05K 2201/10734; H10W 74/15

(57) ABSTRACT

Methods, systems, and devices for a composition of a semiconductor package for cryogenic environments are described. The semiconductor package may include a memory system, a substrate, and a circuit board. The substrate may include a metal core configured with a first strength at temperatures below a threshold associated with a cryogenic environment. The memory system may be coupled with the substrate and include a controller and one or more memory dies. The circuit board may be coupled with the substrate via multiple solder balls and each solder ball of the multiple solder balls may include a high entropy alloy (HEA) core and an indium(In)-doped solder alloy coating around the HEA core.

### CROSS REFERENCE

The present Application for Patent claims priority to U.S. Patent Application No. 63/648,059 by Huang et al., entitled “COMPOSITION OF A SEMICONDUCTOR PACKAGE FOR CRYOGENIC ENVIRONMENTS,” filed May 15, 2024, which is assigned to the assignee hereof, and which is expressly incorporated by reference in its entirety herein.

### TECHNICAL FIELD

The following relates to one or more systems for memory, including a composition of a semiconductor package for cryogenic environments.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports a composition of a semiconductor package for cryogenic environments in accordance with examples as disclosed herein.

FIG. 2 shows an example of a quantum computer that supports a composition of a semiconductor package for cryogenic environments in accordance with examples as disclosed herein.

FIG. 3 shows an example of a semiconductor package that supports a composition of a semiconductor package for cryogenic environments in accordance with examples as disclosed herein.

### DETAILED DESCRIPTION

A memory system may be included in a quantum computer. Quantum computers may utilize quantum physics to store data and perform computations. Because quantum computers rely on properties of quantum physics to operate, quantum computers may be suspectable to high temperature and as such, components of the quantum computers may be kept at low temperatures (e.g., cryogenic temperatures). For example, the memory system of the quantum computer may be kept at a temperature of 77 Kelvin (K) via a cooling medium (e.g., liquid helium (He) or liquid nitrogen (N2)). However, the memory system or structures adjacent to the memory system may not include materials that are suitable for cryogenic conditions. For example, a substrate coupled with the memory system may include an epoxy core which may become brittle over an extended period of time in cryogenic conditions. Thus, it may be beneficial to realize a bill of materials for the memory system or adjacent structure that can withstand long periods of cryogenic conditions.

In some examples, a semiconductor package of a quantum computer may include a memory system, a substrate, and a circuit board. The memory system may be coupled with the substrate and the substrate may be coupled with the circuit board. According to a first example, the substrate may include a metal core that is configured with a first strength at a cryogenic temperature (e.g., 77 K) or the substrate may include a metallic glass core that is configured with a second strength at the cryogenic temperature. Further, the circuit board may be coupled with the substrate via multiple solder balls and each solder balls of the multiple solder balls may include an high entropy alloy (HEA) core and an indium(In)-doped solder alloy coating around the HEA alloy core.

According to a second example, the substrate may be coupled with the memory system via multiple solder balls and each of the solder balls of the multiple solder balls may include an In-doped solder alloy or a Molybdenum(Mo)-based solder alloy. Further, the circuit board may be coupled with the substrate via multiple solder balls and each solder ball of the multiple solder balls may include the In-based solder alloy or the Mo-based solder alloy. Such materials (e.g., the HEA alloy, the In-based solder alloy, and the Mo-based solder alloy) may exhibit higher strength, higher toughness, or higher ductility when compared to other materials at cryogenic temperature which may allow the memory system to operate reliability in the quantum computer.

In addition to applicability in memory systems as described herein, the composition of a semiconductor package for cryogenic conditions may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by extending the life of electronic devices, thereby reducing electronic waste, among other benefits.

Features of the disclosure are illustrated and described in the context of systems, devices, and circuits. Features of the disclosure are further illustrated and described in the context of a quantum computer and a semiconductor package.

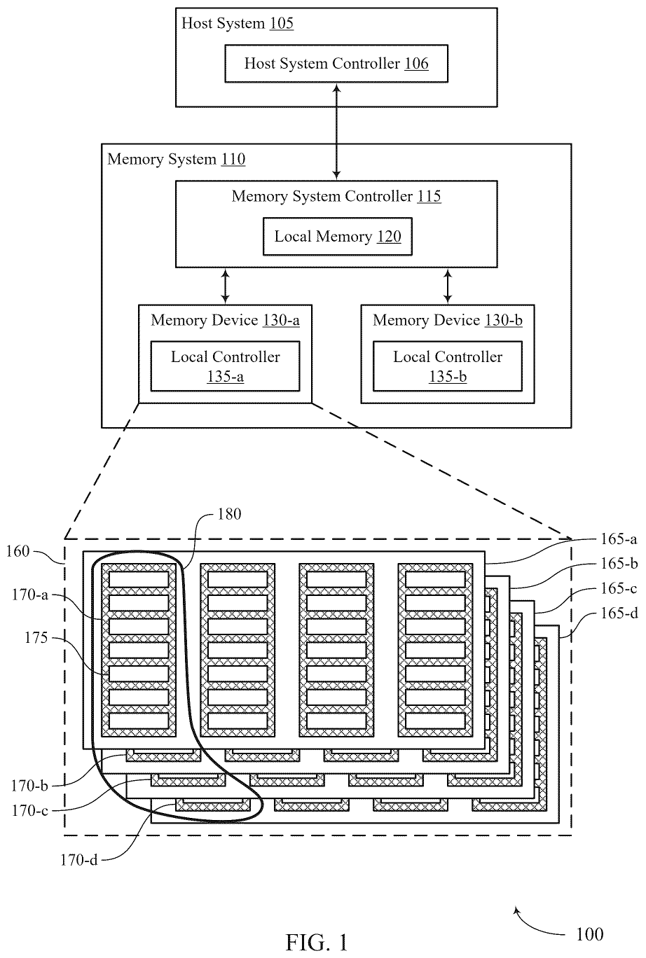

FIG. 1 shows an example of a system 100 that supports a composition of a semiconductor package for cryogenic environments in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells, low power DRAM (LPDRAM) memory cells, or any combination thereof.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b,, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some examples, a semiconductor package of a quantum computer may include the memory system 110, a substrate, and a circuit board. The memory system 110 may be coupled with the substrate and the substrate may be coupled with the circuit board. According to a first example, the substrate may include a metal core that is configured with a first strength at a cryogenic temperature (e.g., at a cryogenic temperature range between 77 K to 200 K) or the substrate may include a metallic glass core that is configured with a second strength at the cryogenic temperature. Further, the circuit board may be coupled with the substrate via multiple solder balls and each solder balls of the multiple solder balls may include a HEA core and an In-doped solder alloy coating around the HEA alloy core.

According to a second example, the substrate may be coupled with the memory system via multiple solder balls and each of the solder balls of the multiple solder balls may include an In-doped solder alloy or a Mo-based solder alloy. Further, the circuit board may be coupled with the substrate via multiple solder balls and each solder ball of the multiple solder balls may include the In-based solder alloy or the Mo-based solder alloy. Such materials (e.g., HEA alloy, In-based solder alloy, or Mo-based solder alloy) may exhibit higher strength, higher toughness, or higher ductility when compared to other materials at cryogenic temperature which may allow the memory system to operate reliability in the quantum computer.

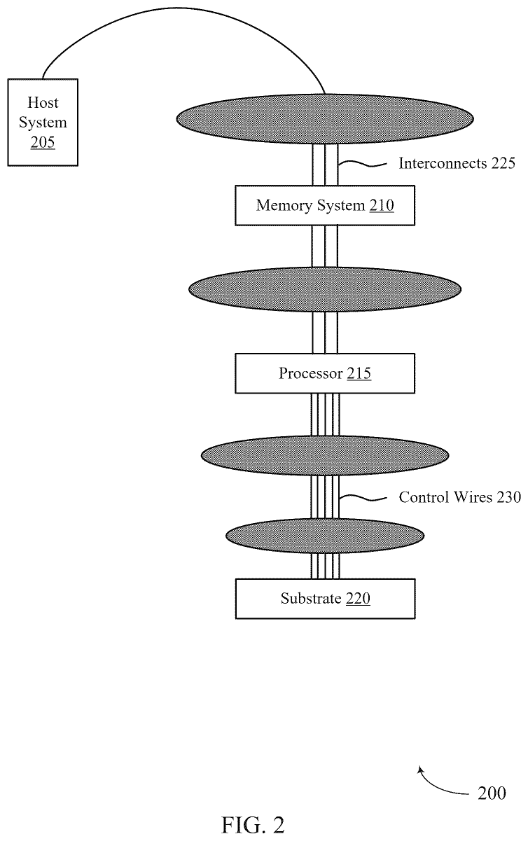

FIG. 2 shows an example of a quantum computer 200 that supports a composition of a semiconductor package for cryogenic environments in accordance with examples as disclosed herein. In some examples, the quantum computer 200 may implement aspects of the system 100. For example, the quantum computer 200 may include a host system 205 and memory system 210 which may be an example of a host system 105 and a memory system 110 as described with reference to FIG. 1, respectively.

The quantum computer 200 may be described as a system that utilizes properties of quantum mechanics to store data and perform computations. As shown in FIG. 2, the quantum computer 200 may include a host system 205, a memory system 210 (e.g., a cryo-complementary metal-oxide-semiconductor (CMOS)), a processor 215 (e.g., a processor that supports Josephson junction logic), and a substrate 220 (e.g., a quantum substrate). The host system 205 may connect with the memory system 210 and the memory system 210 may connect with the processor 215 via low density metal interconnects 225, while the processor 215 may connect with the substrate 220 via high density superconducting wires 230.

Components of the quantum computer 200 may operate in a cryogenic environment. For example, the memory system 210 may operate at 77 K, the processor 215 may operate at 4 K, the high density superconducting wires 230 may operate at 0.1 K, and the substrate 220 may operate at 0.020 K. However, one or more of these components may be unable to withstand the cryogenic environment for extended periods of time. For example, materials of the memory system 210 or materials of structures adjacent to the memory system 210 may become brittle after long periods in the cryogenic environment causing the materials to break down resulting in one or more failures at the quantum computer 200.

As described herein, the memory system 210 and the structures adjacent to the memory system 210 may include cryogenic compatible materials that may allow the memory system 210 to operate in the cryogenic environment for extended periods of time without fail. For example, the memory system 210 may be attached to a substrate via multiple solder balls that include an In-based solder paste or an Mo-based solder paste. Additionally, or alternatively, the substrate may be attached to a circuit board via multiple solder balls that include an HEA core and an In-doped solder alloy coating. Additionally, or alternatively, the substrate may include a metal core or a metallic glass core. Such materials may exhibit high strength (e.g., above a threshold) and high ductility (e.g., above a threshold) allowing the components to withstand cryogenic temperature for an extended period of time.

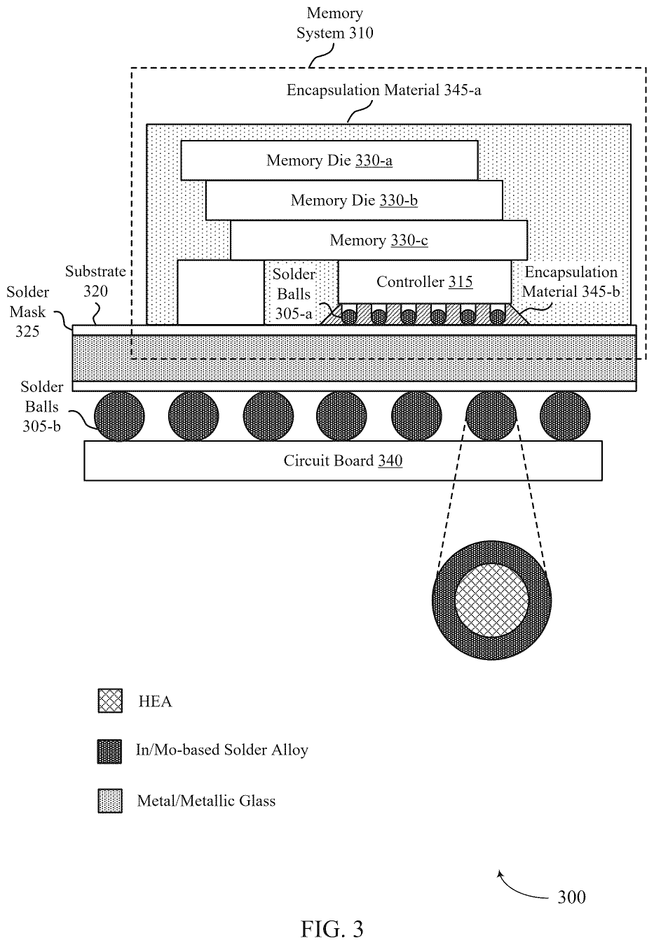

FIG. 3 shows an example of a semiconductor package 300 that supports a composition of a semiconductor package for cryogenic environments in accordance with examples as disclosed herein. In some examples, the semiconductor package 300 may implement aspects of the system 100 and the quantum computer 200. For example, the semiconductor package 300 may include a memory system 310 which may be an example of a memory system 110 or a memory system 210 as described with reference to FIGS. 1 and 2, respectively. Further, the semiconductor package 300 may include memory dies 330 and a controller 315 which may be examples of memory devices 130 and a controller 115 as described with reference to FIG. 1, respectively.

As described with reference to FIG. 2, a quantum computer may include the semiconductor package 300. To ensure smooth operation of the quantum computer, the semiconductor package 300 may operate in cryogenic conditions. Thus, the semiconductor package 300 may include materials that have a higher reliability in cryogenic conditions when compared to the other materials.

In some examples, the semiconductor package 300 may include a circuit board 340 (e.g., a printed circuit board (PCB)). The circuit board 340 may be described as a medium that allows a circuit component (e.g., the memory system 310) to connect with other circuit components (e.g., a host system), for example, using traces and vias. In addition to the circuit board 340, the semiconductor package 300 may include a substrate 320, which may be coupled with the circuit board 340 via solder balls 305-b. Unlike other semiconductor packages, the solder balls 305-b may include an HEA core with an In-based (or In-doped) solder alloy coating.

The HEA used for the core of the solder balls 305-b may include a chromium cobalt nickel (CrCoNi) alloy or a chromium manganese iron cobalt (CrMnFeCoNi) alloy. In some examples, HEAs (e.g., CrCoNi and CrMnFeCoNi) may exhibit a higher strength and a higher ductility at cryogenic conditions when compared to other materials. The In-based solder alloy used for the coating of the solder balls 305-b may include a combination of In and tin (Sn) or a combination of the In, Sn, and silver (Ag). For example, the In-based solder alloy may include In-48Sn, ISA 4805, ISA 4810, or ISA 4815. In-48Sn may include about 48 percent of tin (Sn) and about 58 percent of In. ISA 4805 may include about 48 percent of Sn, about 0.5 percent of Ag, and about 51.5 percent of In. ISA 4810 may include about 48 percent of Sn, about 1.0 percent of Ag, and about 51 percent of In. ISA 4815 may include about 48 percent of Sn, about 1.5 percent of Ag, and about 50.5 percent of In.

As used herein, the term “about” may refer to a range of 1 percent in which a percentage value of an element (e.g., In, Sn, or Ag) may fluctuate. For example, about 48 percent of Sn may include any value from 47 percent to 49 percent of Sn.

In some examples, the substrate 320 may include multiple layers of material. For example, the substrate 320 may include outside layers (e.g., a layer adjacent to the circuit board 340 and a layer adjacent to the memory system 310) which may be collectively referred to as a solder mask 325 of the substrate 320. In some examples, the solder mask 325 of the substrate 320 may include some type of epoxy.

Beneath the layers of the solder mask 325, the substrate 320 may include a metal core. The metal used for the metal core may include any pure metal. For example, the metal core may include nickel (Ni), copper (Cu), Cr, iron (Fe), gold (Au), platinum (Pt), bismuth (Bi), lead (Pb), Sn, zinc (Zn), aluminum (Al), magnesium (Mg), tungsten (W), molybdenum (Mo), Ag, zirconium (Zr), tantalum (Ta), niobium (Nb), or titanium (Ti).

Alternatively, the substrate 320 may include a metallic glass core. An example of the metallic glass used for the core may include any combination of Zr, Cu, Ni, Al, Ti, or Nb. In some examples, pure metals or metallic glasses may exhibit a higher fracture toughness and a higher yield strength at cryogenic conditions when compared to other materials (e.g., epoxies).

In addition to the circuit board 340 and the substrate 320, the semiconductor package 300 may include the memory system 310. As shown in FIG. 3, the memory system 310 may include memory dies 330 (e.g., a memory die 330-a, a memory die 330-b, and a memory die 330-c) and a controller 315 (e.g., a flip chip die). Each of the memory dies 330 may include memory cells configured to store data and each of the memory dies 330 may be coupled with the controller 315. The controller 315 may include circuitry configured to execute operations on the memory dies 330.

In some examples, the memory system 310, or more specifically the controller 315, may be coupled with the substrate 320 via solder balls 305-a (e.g., micro-bumps at the end of the Cu pillars of the controller 315). The solder balls 305-a may include an In-based solder paste. The In-based solder paste used for the solder balls 305-a may include a combination of In and Sn or a combination of In, Sn, and Ag. For example, the In-based solder paste may include In-48Sn, ISA 4805, ISA 4810, or ISA 4815. In some examples, the In-based solder paste used for the solder balls 305-a may be the same or different that the In-based solder alloy used for the coating of the solder balls 305-b. Alternatively, the solder balls 305-a may include an Mo-based solder paste.

In some examples, encapsulation material 345 may surround components of the memory system 310. For example, as shown in FIG. 3, encapsulation material 345-a may surround the memory dies 330, the controller 315, and the solder balls 305-a and the encapsulation material 345-b may surround the solder balls 305-a. The encapsulation material 345 may provide protection (e.g., increased structural integrity) for the components of the memory system 310 (e.g., the memory dies 330, the controller 315, and different interconnects of the memory system 310 (e.g., the solder balls 305-a and fine wires)).

An apparatus is described. The following provides an overview of aspects of the apparatus as described herein:

Aspect 1: A semiconductor package, including: a substrate including a metal core configured with a first strength at temperatures below a threshold associated with a cryogenic environment; a memory system coupled with the substrate, the memory system including a controller and one or more memory dies; and a circuit board coupled with the substrate via a plurality of solder balls, each solder ball of the plurality of solder balls including a HEA core and an In-doped solder alloy coating around the HEA core.

Aspect 2: The semiconductor package of aspect 1, where the HEA core includes a CrCoNi alloy core or a CrMnFeCoNi alloy core.

Aspect 3: The semiconductor package of any of aspects 1 through 2, where the metal core includes a pure metal.

Aspect 4: The semiconductor package of aspect 3, where the pure metal includes Ni, Cu, Cr, Fe, Au, Pt, Bi, Pb, Sn, Zn, Al, Mg, W, Mo, Ag, Zr, Ta, Nb, or Ti.

Aspect 5: The semiconductor package of any of aspects 1 through 4, where the In-doped solder alloy coating includes about 52 percent of In and about 48 percent of Sn.

Aspect 6: The semiconductor package of any of aspects 1 through 5, where the indium-doped solder alloy coating includes about 48 percent of Sn, a range of 0.5 percent to 1.5 percent of Ag, and a range of 50.5 percent to 51.5 percent of In.

Aspect 7: The semiconductor package of any of aspects 1 through 6, where the memory system is coupled with the substrate via a second plurality of solder balls, each solder ball of the second plurality of solder balls including an In-based solder alloy or a Mo-based solder alloy.

Aspect 8: The semiconductor package of aspect 7, where the indium-based solder alloy includes about 48 percent of Sn, a range of 0.5 percent to 1.5 percent of Ag, and a range of 50.5 percent to 51.5 percent of In.

An apparatus is described. The following provides an overview of aspects of the apparatus as described herein:

Aspect 9: A semiconductor package, including: a substrate including a metallic glass core configured with a first strength at temperatures below a threshold associated with a cryogenic environment; a memory system coupled with the substrate, the memory system including a controller and one or more memory dies; and a circuit board coupled with the substrate via a plurality of solder balls, each solder ball of the plurality of solder balls including a HEA core and an In-doped solder alloy coating around the HEA core.

Aspect 10: The semiconductor package of aspect 9, where the HEA core includes a CrCoNi alloy core or a CrMnFeCoNi alloy core.

Aspect 11: The semiconductor package of any of aspects 9 through 10, where the metallic glass core includes any combination of Zr, Cu, Ni, Al, Ti, Ag, or Nb.

Aspect 12: The semiconductor package of any of aspects 9 through 11, where the In-doped solder alloy coating includes about 52 percent of In and about 48 percent of Sn.

Aspect 13: The semiconductor package of any of aspects 9 through 12, where the In-doped solder alloy coating includes about 48 percent of Sn, a range of 0.5 percent to 1.5 percent of Ag, and a range of 50.5 percent to 51.5 percent of In.

Aspect 14: The semiconductor package of any of aspects 9 through 13, where the memory system is coupled with the substrate via a second plurality of solder balls, each solder ball of the second plurality of solder balls including an In-based solder alloy or a Mo-based solder alloy.

Aspect 15: The semiconductor package of aspect 14, where the In-based solder alloy includes about 48 percent of Sn, about 0.5 percent of Ag, and about 51.5 percent of In.

Aspect 16: The semiconductor package of any of aspects 14 through 15, where the In-based solder alloy includes about 48 percent of Sn, a range of 0.5 percent to 1.5 percent of Ag, and a range of 50.5 percent to 51.5 percent of In.

An apparatus is described. The following provides an overview of aspects of the apparatus as described herein:

Aspect 17: A semiconductor package, including: a memory system including a controller and one or more memory dies; a substrate coupled with the memory system via a first plurality of solder balls, each solder ball of the first plurality of solder balls including an In-based solder alloy or a Mo-based solder alloy; and a circuit board coupled with the substrate via a second plurality of solder balls, each solder ball of the second plurality of solder balls including the In-based solder alloy or the Mo-based solder alloy.

Aspect 18: The semiconductor package of aspect 17, where the In-based solder alloy includes about 48 percent of Sn, about 0.5 percent of Ag, and about 51.5 percent of In.

Aspect 19: The semiconductor package of any of aspects 17 through 18, where the In-based solder alloy includes about 48 percent of Sn, a range of 0.5 percent to 1.5 percent of Ag, and a range of 50.5 percent to 51.5 percent of In.

Aspect 20: The semiconductor package of any of aspects 17 through 19, where the substrate includes a metal core or a metallic glass core.

Aspect 21: The semiconductor package of aspect 20, where the metal core includes a pure metal.

Aspect 22: The semiconductor package of aspect 21, where the pure metal includes Ni, Cu, Cr, Fe, Au, Pt, Bi, Pb, Sn, Zn, Al, Mg, W, Mo, Ag, Zr, Ta, Nb, or Ti.

Aspect 23: The semiconductor package of any of aspects 20 through 22, where the metallic glass core includes any combination of Zr, Cu, Ni, Al, Ti, Ag, or Nb.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor package, comprising:
a substrate comprising a metal core configured with a first strength at temperatures below a threshold associated with a cryogenic environment;
a memory system coupled with the substrate, the memory system comprising a controller and one or more memory dies; and
a circuit board coupled with the substrate via a plurality of solder balls, each solder ball of the plurality of solder balls comprising a high entropy alloy core and an indium-doped solder alloy coating around the high entropy alloy core.

2. The semiconductor package of claim 1, wherein the high entropy alloy core comprises a chromium cobalt nickel alloy core or a chromium manganese iron cobalt nickel alloy core.

3. The semiconductor package of claim 1, wherein the metal core comprises a pure metal.

4. The semiconductor package of claim 3, wherein the pure metal comprises nickel, copper, chromium, iron, gold, platinum, bismuth, lead, tin, zinc, aluminum, magnesium, tungsten, molybdenum, silver, zirconium, tantalum, niobium, or titanium.

5. The semiconductor package of claim 1, wherein the indium-doped solder alloy coating comprises about 52 percent of indium and about 48 percent of tin.

6. The semiconductor package of claim 1, wherein the indium-doped solder alloy coating comprises about 48 percent of tin, a range of 0.5 percent to 1.5 percent of silver, and a range of 50.5 percent to 51.5 percent of indium.

7. The semiconductor package of claim 1, wherein the memory system is coupled with the substrate via a second plurality of solder balls, each solder ball of the second plurality of solder balls comprising an indium-based solder alloy or a molybdenum-based solder alloy.

8. The semiconductor package of claim 7, wherein the indium-based solder alloy comprises about 48 percent of tin, a range of 0.5 percent to 1.5 percent of silver, and a range of 50.5 percent to 51.5 percent of indium.

9. A semiconductor package, comprising:
a substrate comprising a metallic glass core configured with a first strength at temperatures below a threshold associated with a cryogenic environment;
a memory system coupled with the substrate, the memory system comprising a controller and one or more memory dies; and
a circuit board coupled with the substrate via a plurality of solder balls, each solder ball of the plurality of solder balls comprising a high entropy alloy core and an indium-doped solder alloy coating around the high entropy alloy core.

10. The semiconductor package of claim 9, wherein the high entropy alloy core comprises chromium cobalt nickel alloy or chromium manganese iron cobalt nickel alloy.

11. The semiconductor package of claim 9, wherein the metallic glass core comprises any combination of zirconium, copper, nickel, aluminum, titanium, silver, or niobium.

12. The semiconductor package of claim 9, wherein the indium-doped solder alloy coating comprises about 52 percent of indium and about 48 percent of tin.

13. The semiconductor package of claim 9, wherein the indium-doped solder alloy coating comprises about 48 percent of tin, a range of 0.5 percent to 1.5 percent of silver, and a range of 50.5 percent to 51.5 percent of indium.

14. The semiconductor package of claim 9, wherein the memory system is coupled with the substrate via a second plurality of solder balls, each solder ball of the second plurality of solder balls comprising an indium-based solder alloy or a molybdenum-based solder alloy.

15. The semiconductor package of claim 14, wherein the indium-based solder alloy comprises about 48 percent of tin, about 0.5 percent of silver, and about 51.5 percent of indium.

16. The semiconductor package of claim 14, wherein the indium-based solder alloy comprises about 48 percent of tin, a range of 0.5 percent to 1.5 percent of silver, and a range of 50.5 percent to 51.5 percent of indium.

17. A semiconductor package, comprising:
a memory system comprising a controller and one or more memory dies;
a substrate coupled with the memory system via a first plurality of solder balls, each solder ball of the first plurality of solder balls comprising an indium-based solder alloy or a molybdenum-based solder alloy; and
a circuit board coupled with the substrate via a second plurality of solder balls, each solder ball of the second plurality of solder balls comprising the indium-based solder alloy or the molybdenum-based solder alloy.

18. The semiconductor package of claim 17, wherein the indium-based solder alloy comprises about 48 percent of tin, about 0.5 percent of silver, and about 51.5 percent of indium.

19. The semiconductor package of claim 17, wherein the indium-based solder alloy comprises about 48 percent of tin, a range of 0.5 percent to 1.5 percent of silver, and a range of 50.5 percent to 51.5 percent of indium.

20. The semiconductor package of claim 17, wherein the substrate comprises a metal core or a metallic glass core.

21. The semiconductor package of claim 20, wherein the metal core comprises a pure metal.

22. The semiconductor package of claim 21, wherein the pure metal comprises nickel, copper, chromium, iron, gold, platinum, bismuth, lead, tin, zinc, aluminum, magnesium, tungsten, molybdenum, silver, zirconium, tantalum, niobium, or titanium.

23. The semiconductor package of claim 20, wherein the metallic glass core comprises any combination of zirconium, copper, nickel, aluminum, titanium, silver, or niobium.
